(19) United States
(12) Patent Application Publication
(10) Pub. No.: US 2019/0018087 A1
(43) Pub. Date: Jan. 17, 2019

(54) MAGNETOMETER WITH TUBULAR LIGHT PIPE

(71) Applicant: LOCKHEED MARTIN CORPORATION, Bethesda, MD (US)

(72) Inventors: Joseph W. HAHN, Bethesda, MD (US); Yongdan HU, Bethesda, MD (US); Wilbur LEW, Bethesda, MD (US)

(73) Assignee: LOCKHEED MARTIN CORPORATION, Bethesda, MD (US)

(21) Appl. No.: 16/032,060

(22) Filed: Jul. 10, 2018

Related U.S. Application Data
(60) Provisional application No. 62/531,334, filed on Jul. 11, 2017.

(51) Int. Cl. G01R 33/26; G01R 33/32

(52) U.S. Cl. CPC G01R 33/26; G01R 33/323

(57) ABSTRACT

Systems and methods using a magneto-optical defect center material magnetic sensor system that uses fluorescence intensity to distinguish the mₛ=±1 states, and to measure the magnetic field based on the energy difference between the mₛ=+1 state and the mₛ=−1 state, as manifested by the RF frequencies corresponding to each state in some embodiments. The system may include an optical excitation source, which directs optical excitation to the material. The system may further include an RF excitation source, which provides RF radiation to the material. Light from the material may be directed through an optical waveguide assembly comprising an optical waveguide with a hollow core and at least one optical filter coating.

### CROSS-REFERENCE TO RELATED APPLICATIONS

This application claims the benefit of and priority to U.S. Provisional Application No. 62/531,334 filed on Jul. 11, 2017, the entire disclosure of which is incorporated by reference herein.

### FIELD

The present disclosure generally relates to magnetic sensor systems, and more particularly, to magnetic sensor systems including a magneto-optical defect center material, with a plurality of magneto-optical defect centers.

### BACKGROUND

Many advanced magnetic imaging systems can operate in limited conditions, for example, high vacuum and/or cryogenic temperatures, which can make them inapplicable for imaging applications that require ambient conditions. Small size, weight and power (SWAP) magnetic sensors of moderate sensitivity, vector accuracy, and bandwidth are valuable in many applications.

### SUMMARY

According to certain embodiments, a system for magnetic detection may include: a magneto-optical defect center material comprising a plurality of defect centers; a radio frequency (RF) excitation source configured to provide RF excitation to the magneto-optical defect center material; an optical detector configured to receive an optical signal emitted by the magneto-optical defect center material; an optical light source; and an optical waveguide assembly. The optical waveguide assembly may include an optical waveguide and at least one optical filter coating. The optical waveguide assembly may be an optical waveguide with a hollow core and at least one optical filter coating, wherein the optical waveguide assembly may be configured to transmit light emitted from the magneto-optical defect center material to the optical detector through the at least one optical filter coating. Magneto-optical defect center materials include but are not limited to diamonds, Silicon Carbide (SiC) and other materials with nitrogen, boron, or other defect centers.

According to certain embodiments, the optical waveguide includes a light pipe with a hollow core where the inside surface of the light pipe may be coated in silver. According to certain embodiments, the optical filter coating transmits greater than about 99% of light with a wavelength of about 650 nm to about 850 nm. According to certain embodiments, the optical filter coating transmits less than 0.1% of light with a wavelength of less than about 600 nm. According to certain embodiments, the optical filter coating transmits greater than about 99% of light with a wavelength of about 650 nm to about 850 nm, and transmits less than 0.1% of light with a wavelength of less than about 600 nm. According to certain embodiments, the optical filter coating may be disposed on an end surface of the optical waveguide adjacent the optical detector. According to certain embodiments, a first optical filter coating may be disposed on an end surface of the optical waveguide adjacent the optical detector, and a second optical filter coating may be disposed on an end surface of the optical waveguide adjacent the NV diamond material.

According to certain embodiments, a method of magnetic detection using a magneto-optical defect material comprising a plurality of defect centers may comprise: providing radio frequency (RF) excitation to the magneto-optical defect material by an RF excitation source, transmitting light emitted from the magneto-optical defect material to an optical detector using a waveguide assembly comprising an optical waveguide with a hollow core and at least one optical filter coating, wherein the optical waveguide assembly may be configured to transmit light emitted from the magneto-optical defect center material to the optical detector through the at least one optical filter coating, and receiving an optical signal comprising the light emitted by the magneto-optical defect material by the optical detector.

According to certain embodiments, a system for magnetic detection may include: a magneto-optical defect material comprising a plurality of defect centers; a means for providing RF excitation to the NV diamond material; a means for receiving an optical signal emitted by the NV diamond material by an optical detector; an optical light source; and a means for transmitting light emitted from the NV diamond material to the optical detector using an optical waveguide with a hollow core and at least one optical filter coating, wherein the optical waveguide assembly may be configured to transmit light emitted from the magneto-optical defect center material to the optical detector through the at least one optical filter coating.

According to certain embodiments a magneto-optical defect center magnetometer may include a magneto-optical defect center material comprising a plurality of magneto-optical defect centers, a lens assembly with a red filter configured to direct light from the magneto-optical defect center material, and a light pipe configured to operably connect to the lens assembly to transmit red light. In some embodiments, the magnetometer may further comprise an optical light source configured to direct light at the magneto-optical defect center material. In some embodiments, the magnetometer may further comprise a laser position adjustment flexure rib array configured to adjust a position of the optical light source, wherein the optical light source is a laser diode. In some embodiments, the magnetometer may further comprise a laser angle adjustment flexure rib configured to adjust an angle of the optical light source. In some embodiments, the magnetometer may further comprise an optical excitation focusing lens cell and a photo diode, wherein the optical excitation focusing lens cell is configured to focus light coming from an exit of the light pipe on to the photo diode. In some embodiments, the light pipe may comprise a metallic light pipe comprising a hollow core, coated on the inner surface with silver.

### BRIEF DESCRIPTION OF THE DRAWINGS

FIG. 1 illustrates an optical excitation assembly as a cross-section including light pipes in some embodiments.

FIG. 2 illustrates a light pipe with body mount in some embodiments.

FIG. 3 illustrates a schematic diagram of a magneto-optical defect center material magnetic sensor system in some embodiments.

FIG. 4 illustrates a magneto-optical defect center in a magneto-optical defect center material in accordance with some illustrative embodiments.

FIG. 5 illustrates an energy level diagram showing energy levels of spin states for a magneto-optical defect center in accordance with some illustrative embodiments.

FIG. 6 is a graph illustrating the fluorescence as a function of an applied RF frequency of a magneto-optical defect center along a given direction for a zero magnetic field in accordance with some illustrative embodiments.

FIG. 7 is a graph illustrating the fluorescence as a function of an applied RF frequency for four different magneto-optical defect center orientations for a non-zero magnetic field in accordance with some illustrative embodiments.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Magneto-optical defect center materials such as diamonds with nitrogen vacancy (NV) centers can be used to detect magnetic fields. Green light which enters a diamond structure with NV centers interacts with NV centers, and red light is emitted from the diamond. The amount of red light emitted can be used to determine the strength of the magnetic field. The efficiency and accuracy of sensors using magneto-optical defect center materials such as diamonds with NV centers (DNV sensors) is increased by transferring as much light as possible from the NV centers to the photo sensor that measures the amount of red light. Magneto-optical defect center materials include but are not be limited to diamonds, Silicon Carbide (SiC) and other materials with nitrogen, boron, or other chemical defect centers.

In some implementations, a coated, hollow light pipe may be used to improve the optics and specifically the light collection efficiency in an optical defect center based magnetometer where the light collection optics directly relate to the performance of the magnetometer. While solid glass or other manufactured solid optical material light pipes may be used, such solid light pipes may suffer from efficiency issues. Solid light pipes have at least the efficiency issues of entrance loss, where some of the light entering the light pipe may be reflected, absorption, where the solid material attenuates some of the light through the length of the pipe through absorption, escape of light through the sides of the light pipe, where light hitting an edge of the light pipe at an angle beyond the angle for total internal reflection escapes through the side of the light pipe, and exit loss, where some of the light exiting the solid material light pipe may be reflected back into it.

A tubular, hollow light pipe has the benefits of no entrance loss or exit loss because the tube is not a solid material but rather hollow in the middle where the light may be traveling. There may be nearly no attenuation loss because the hollow center of the tube where the light travels is full of air, which over the length of most light pipes has no measurable attenuation of the light. In some embodiments, there are no or reduced escape issues from the total internal reflection because the reflective coating on the inside of the hollow portion of the light pipe directs the light from the entrance side to the exit side. If a reflective coating is used, there may be some amount of light that, but still much less absorption than through a solid material light pipe.

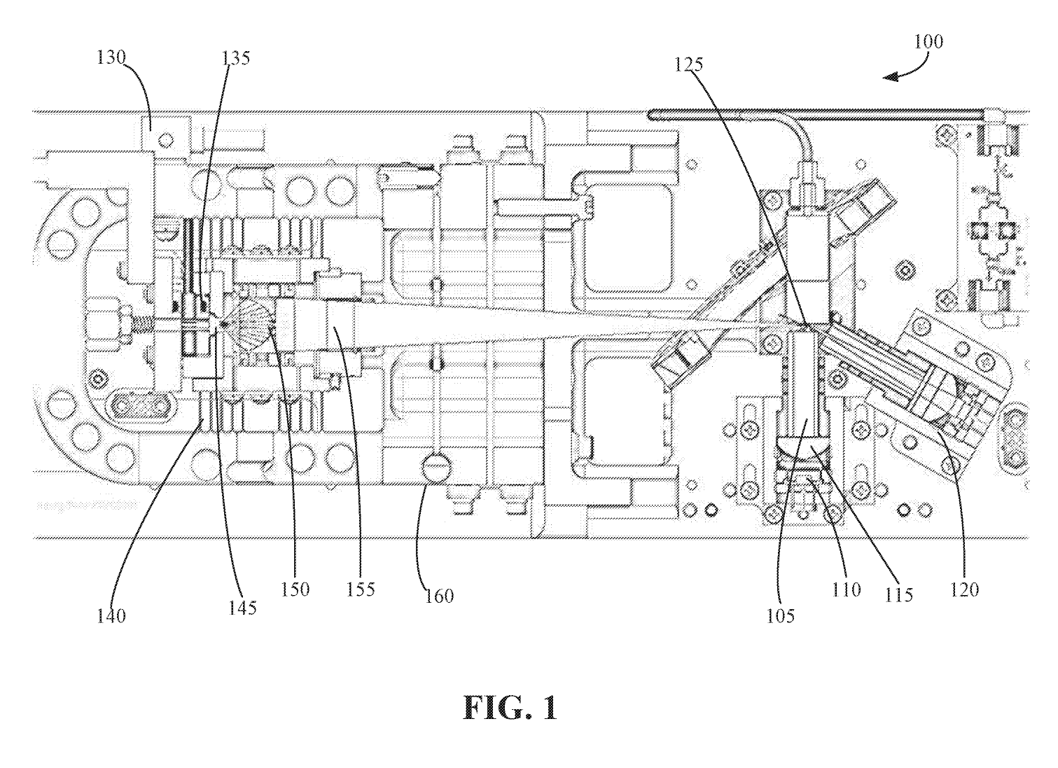

FIG. 1 illustrates an optical excitation assembly 100 as a cross-section including light pipes in accordance with some embodiments. The optical excitation assembly 100 includes, in brief, a first light pipe 105, a photo diode 110 (e.g., a photo diode for detecting red light), a lens assembly with red filter 115, a second light pipe assembly 120 (with similar corresponding assembly to the first light pipe 105 but for detecting green light), a magneto-optical defect center material with defect centers 125, an accelerometer 130, one or more thermistors 135, laser position adjustment flexure rib array 140, an optical excitation module 145, an optical excitation focusing lens cell 150, a waveplate for laser polarization control 155, and a laser angle adjustment flexure rib 160.

Still referring to FIG. 1 and in further detail, the optical excitation assembly 100 comprises a first light pipe 105. In some embodiments, the first light pipe 105 may be configured to operably connect to an assembly for detecting red light (e.g., using a photo diode 110 configured to detect red light). The first light pipe 105 may have any appropriate geometry. In some embodiments, the first light pipe 105 may be cylindrical and hollow. The hollow inside surface may be coated with a reflective surface. In some embodiments, the first light pipe 105 comprises a copper structure, silver inner reflective surface, and gold outer surface. A light pipe with such a structure may have approximately 95% reflection at a wavelength of light of 515 nm. In some embodiments, the reflection increases as the wavelength increases. In some embodiments, the first light pipe 105 may be configured to be mountable as outer points of the light pipe can be contacted without increasing emission loss from the light pipe. In some embodiments, the first light pipe 105 may have a circular cross-section, square cross-section, rectangular cross-section, hexagonal cross-section, or octagonal cross-section. In some embodiments, the light pipe may be a tubular piece of glass or metal (e.g., copper) that may be hollow on the inside and that has an inside surface coated with a reflective coating that directs light from the entrance side to the exit side such that the first light pipe 105 functions as a light pipe. The first light pipe 105 may be formed from any appropriate material (e.g., copper structure). In some embodiments, the optical excitation assembly 100 comprises a second light pipe assembly 120. In some embodiments, the second light pipe assembly 120 comprises a second light pipe configured to operably connect to the assembly for detecting green light similar to the above configuration for the first light pipe 105.

The light pipe can be selected to have an appropriate aperture size. The aperture of the light pipe can be selected to be matched to or smaller than the optical detector. This size relationship allows the optical detector to capture the highest possible percentage of the light emitted by the light pipe. The aperture of the light pipe can be also selected to be larger than the surface of the diamond material to which it may be coupled. This size relationship allows the light pipe to capture the highest possible percentage of light emitted by the magneto-optical defect center material. In some embodiments, the light pipe may have an aperture of about 4 mm. In some other embodiments, the light pipe may have an aperture of about 2 mm. In some embodiments, the light pipe may have an aperture of 4 mm, and the magneto-optical defect material may have a coupled surface with a height of 0.6 mm and a length of 2 mm, or less. The light pipe may have any appropriate length, such as about 25 mm. The light pipe can be positioned such that the end surface of the light pipe adjacent the magneto-optical material may be parallel, or substantially parallel, to the associated surface of the magneto-optical material. This arrangement allows the light pipe to capture an increased amount of the light emitted by the magneto-optical defect center material as possible. The alignment of the surfaces of the light pipe and the magneto-optical defect center material ensures that a maximum amount of the light emitted by the magneto-optical defect center material will intersect the end surface of the light pipe, thereby being captured by the light pipe.

The optical excitation assembly 100 comprises a photo diode 110. In some embodiments, the photo diode 110 may be configured to collect light (e.g., red or green light collection).

The optical excitation assembly 100 comprises a lens assembly with red filter 115. In some implementations, light from the magneto-optical defect center material 125 may be directed through the lens assembly with red filter 115 to filter out light in the excitation band (in the green, for example), and to pass light in the red fluorescence band. The lens assembly with red filter 115 may be any appropriate optical filter capable of transmitting red light and reflecting other light, such as green light. In some embodiments, the red filter may be a coating applied to an end surface of the lens assembly. The coating may be any appropriate anti-reflection coating for red light. In some embodiments, the anti-reflective coating may exhibit greater than 99% transmittance for light in the wavelength range of about 650 nm to about 850 nm. Preferably, the anti-reflective coating may exhibit greater than 99.9% transmittance for light in the wavelength range of about 650 nm to about 850 nm. The optical filter 650 may be disposed on an end surface of the lens 225 assembly adjacent to the light pipe. In some embodiments, the red filter 115 may also be highly reflective for light other than red light, such as green light. Such an optical filter may be a dichroic coating or multiple coatings with the desired cumulative optical properties. The optical filter may exhibit less than about 0.1% transmittance for light with a wavelength of less than about 600 nm. Preferably, the optical filter may exhibit less than about 0.01% transmittance for light with a wavelength of less than about 600 nm. In some embodiments, the optical excitation assembly 100 comprises a second light pipe assembly comprising a lens configured similarly with a green light filter. In some implementations, light from the magneto-optical defect center material 125 may be directed through the lens to filter out light in the excitation band (in the red, for example), and to pass light in the green fluorescence band. The filter in the second light pipe assembly 120 may be any appropriate optical filter capable of transmitting green light and reflecting other light, such as red light. In some embodiments, the green filter may be a coating applied to an end surface of the lens. The coating may be any appropriate anti-reflection coating for green light.

The filter(s) may be a coating formed by any appropriate method. In some embodiments, the filter(s) may be formed by an ion beam sputtering (IBS) process. The coating may be a single-layer coating or a multi-layer coating. The coating may include any appropriate material, such as magnesium fluoride, silica, hafnia, or tantalum pentoxide. The material for the coating may be selected based on the light pipe material and the material which the coating will be in contact with, such as an optical coupling material, to produce the desired optical properties. The coating may have a hardness that approximately matches the hardness of the light pipe. The coating may have a high density, and exhibit good stability with respect to humidity and temperature.

The optical excitation assembly 100 comprises a magneto-optical defect center material with defect centers 125. In general, a variety of different magneto-optical defect center material, with a variety of magneto-optical defect centers can be used (e.g., diamond with nitrogen vacancy defect centers). Magneto-optical defect center materials include but are not be limited to diamonds, Silicon Carbide (SiC) and other materials with nitrogen, boron, or other defect centers.

In some embodiments, the optical excitation assembly 100 further comprises an accelerometer 130, one or more thermistors 135, a laser position adjustment flexure rib array 140, and a laser angle adjustment flexure rib 160. The optical excitation assembly 100 comprises an optical excitation module 145. The optical excitation module 145 may be a directed light source. In some embodiments, the optical excitation module 145 may be a light emitting diode. In some embodiments, the optical excitation module 145 may be a laser diode.

The optical excitation assembly 100 comprises an optical excitation focusing lens cell 150. In some embodiments, the optical excitation focusing lens cell 150 may be configured to focus light coming from the exit of a light pipe (e.g., a first light pipe 105) on to a photo diode for collection.

The optical excitation assembly 100 comprises a waveplate for laser polarization control 155. In some embodiments, the waveplate may be a half-wave plate. In some embodiments, the waveplate may be a quarter-wave plate. The waveplate may be configured to be rotated relative to the optical excitation assembly 100 in order to change the polarization of the light (e.g., laser light).

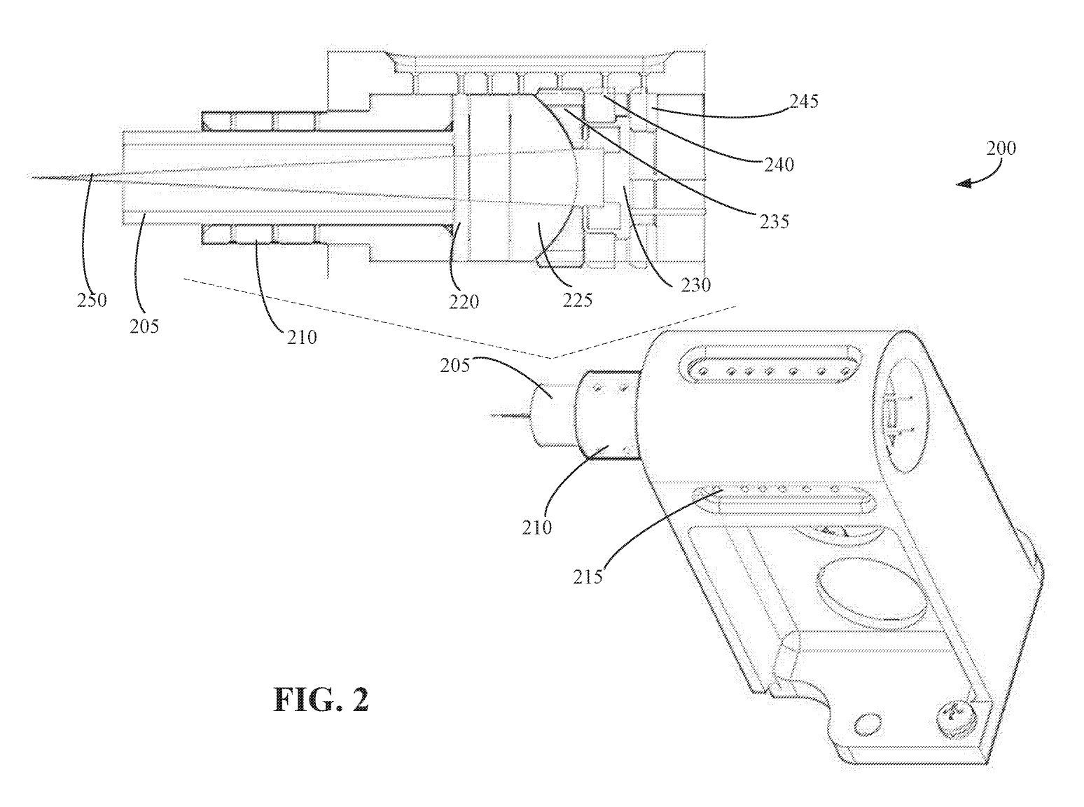

FIG. 2 depicts a light pipe with body mount 200 illustrated in accordance with some embodiments. The figure also shows across section as viewed from above of a portion of body mount including the light pipe. The light pipe with body mount 200 includes, in brief, a light pipe tube 205 (e.g., hollow light pipe tube), a light pipe mount 210, holes for staking optics for vibration 215, one or more filters 220, a lens 225, a photo diode 230, a lens retaining ring 235, a photo diode mount 240, and a photo diode retaining ring 245. A representation of a light path 250 is also shown.

Still referring to FIG. 2 and in further detail, the light pipe with body mount 200 comprises a light pipe tube 205. In some embodiments, the light pipe tube 205 may be configured to operably connect to an assembly for detecting red light or green light (e.g., using a photo diode 230 configured to detect red light or green light). The light pipe tube 205 may have any appropriate geometry. In some embodiments, the light pipe tube 205 may be cylindrical and hollow. The hollow inside surface may be coated with a reflective surface. In some embodiments, the light pipe tube 205 comprises a copper structure, silver inner reflective surface, and gold outer surface. A light pipe with such a structure may have approximately 95% reflection at a wavelength of light of 515 nm. In some embodiments, the reflection increases as the wavelength increases. In some embodiments, the light pipe tube 205 may be configured to be mountable as outer points of the light pipe can be contacted without increasing emission loss from the light pipe. In some embodiments, the light pipe tube 205 may have a circular cross-section, square cross-section, rectangular cross-section, hexagonal cross-section, or octagonal cross-section. In some embodiments, the light pipe tube 205 may be a tubular piece of glass or metal (e.g., copper) that may be hollow on the inside and that has an inside surface coated with a reflective coating that directs light from the entrance side to the exit side such that the light pipe tube 205 functions as a light pipe. The light pipe tube 205 may be formed from any appropriate material (e.g., copper structure with reflective coatings).

The light pipe with body mount 200 comprises a light pipe mount 210. The light pipe mount 210 can be made of any material (e.g., plastic) that can hold the light pipe securely. Since, the performance of the hollow light pipe (e.g., light pipe tube 205) is not diminished by contact or mounting points, the light pipe mount 210 can be configured to hold the light pipe (e.g., light pipe tube 205) securely. The light pipe with body mount 200 may further comprise holes for staking optics for vibration 215.

The light pipe with body mount 200 comprises one or more filters 220. The filter(s) may be a coating formed by any appropriate method. In some embodiments, the filter(s) may be formed by an ion beam sputtering (IBS) process. The coating may be a single-layer coating or a multi-layer coating. The coating may include any appropriate material, such as magnesium fluoride, silica, hafnia, or tantalum pentoxide. The material for the coating may be selected based on the light pipe material and the material which the coating will be in contact with, such as an optical coupling material, to produce the desired optical properties. The coating may have a hardness that approximately matches the hardness of the light pipe. The coating may have a high density, and exhibit good stability with respect to humidity and temperature.

The light pipe with body mount 200 comprises a lens 225. In some embodiments, the lens 225 may be configured to focus light coming from the exit of a light pipe (e.g., light pipe tube 205) on to a photo diode for collection. In some embodiments, the light pipe with body mount 200 comprises a photo diode 230. In some embodiments, the photo diode 230 may be configured to collect light (e.g., red or green light collection). In some embodiments, the lens 225 may be held in place by a lens retaining ring 235 and the photo diode (e.g., photo diode 230) may be held in place by a photo diode mount 240 and photo diode retaining ring 245. In some implementations, an optical coupling material may be disposed between one or more of a light pipe, filter, magneto-optical defect material, photo diode, and lens as described in various embodiments. The optical coupling material may be any appropriate optical coupling material, such as a gel or epoxy. In some embodiments, the optical coupling material may be selected to have optical properties, such as an index of refraction, that improves the light transmission between the coupled components. The coupling material may be in the form of a layer formed between the components to be coupled. In some embodiments, the coupling material layer may have a thickness of about 1 microns to about 5 microns. The coupling material may serve to eliminate air gaps between the components to be coupled, increasing the light transmission efficiency. The coupling material may produce a light transmission between the components to be coupled that is functionally equivalent to direct contact between the components to be coupled. In some embodiments, an epoxy coupling material may also serve to mount the magneto-optical defect material to the optical waveguide assembly, such that other supports for material are not required. In some embodiments, a coupling material may not be necessary where direct contact between the optical filter or light pipe and the optical detector is achieved. Similarly, a coupling material may not be necessary where direct contact between the light pipe and the magneto-optical defect center material is achieved.

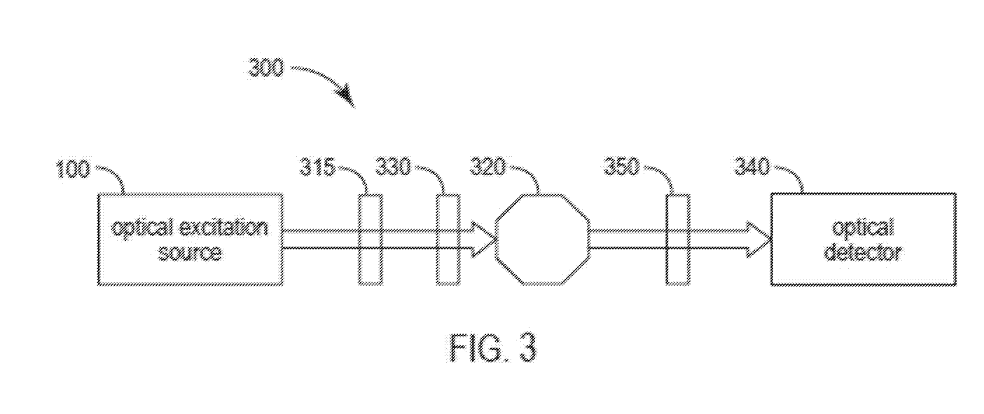

FIG. 3 is a schematic diagram illustrating a conventional NV center magnetic sensor system 300 that uses fluorescence intensity to distinguish the mₛ=±1 states, and to measure the magnetic field based on the energy difference between the mₛ=+1 state and the mₛ=−1 state. The system 300 includes an optical excitation source 100, which directs optical excitation through a half-wave plate 315 to a magneto-optical defect center material 320 with defect centers (e.g, NV diamond material). The system further includes an RF excitation source 330, which provides RF radiation to the magneto-optical defect center material 320. Light from the NV diamond may be directed through an optical filter 350 to an optical detector 340.

In some implementations, the RF excitation source 330 may be a microwave coil. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, or between the mₛ=0 spin state and the mₛ=+1 spin state, there is a decrease in the fluorescence intensity.

In some implementations, the optical excitation source 100 may comprise a laser or a light emitting diode which emits light in the green. In some implementations, the optical excitation source 100 induces fluorescence in the red, which corresponds to an electronic transition from the excited state to the ground state. In some implementations, the light from the optical excitation source 100 is directed through a half-wave plate 315. In some implementations, light from the Magneto-optical defect center material 320 is directed through the optical filter 350 to filter out light in the excitation band (in the green, for example), and to pass light in the red fluorescence band, which in turn may be detected by the detector 340. The optical excitation light source 100, in addition to exciting fluorescence in the diamond material 320, also serves to reset the population of the mₛ=0 spin state of the ground state ³A₂ to a maximum polarization, or other desired polarization.

In some implementations, the light may be directed through a half-wave plate 315. In some implementations, the half-wave plate 315 may be in a shape analogous to a cylinder solid with an axis, height, and a base. In some implementations, the performance of the system may be affected by the polarization of the light (e.g., light from a laser) as it may be lined up with a crystal structure of the magneto-optical defect center material 320. In some implementations, a half-wave plate 315 may be mounted to allow for rotation of the half-wave plate 315 with the ability to stop and/or lock the half-wave plate 315 into position at a specific rotation. This allows the tuning of the polarization relative to the magneto-optical defect center material 320. Affecting the performance of the system allows for the affecting of the performance of the Lorentzians (Lorentzian magnetic fields). In some implementations, when a laser polarization may be lined up with the orientation of a given lattice of the magneto-optical defect center material 320, the contrast of the dimming Lorentzian, the portion of the light sensitive to magnetic fields, may be deepest and narrowest such that the slope of each side of the Lorentzian is steepest. In some implementations, a laser polarization lined up with the orientation of a given lattice of the magneto-optical defect center material 320 allows extraction of maximum sensitivity of the lattice (i.e., maximum sensitivity of a BCO vector in free space. In some implementations, four positions of the half-wave plate 315 are determined to maximize the sensitivity to different lattices of the magneto-optical defect center material 320. In some implementations, a position of the half-wave plate 315 may be determined to get similar sensitivities to the four Lorentzians corresponding to lattices of the magneto-optical defect center material 320.

In some implementations, a position of the half-wave plate 315 may be determined as an initial calibration for a light directed through a half-wave plate 315. In some implementations, the performance of the system may be affected by the polarization of the light (e.g., light from a laser) as it may be lined up with a crystal structure of the magneto-optical defect center material 320. In some implementations, a half-wave plate 315 may be mounted to allow for rotation of the half-wave plate 315 with the ability to stop and/or lock the half-wave after an initial calibration determines the eight Lorentzians associated with a given lattice with each pair of Lorentzians associated with a given lattice plane symmetric around the carrier frequency. In some implementations, the initial calibration may be set to allow for high contrast with steep Lorentzians for a particular lattice plane. In some implementations, the initial calibration may be set to create similar contrast and steepness of the Lorentzians for each of the four lattice planes.

In various embodiments described herein, the material with the defect centers may be formed in a shape that directs light from the defect centers towards the photo diode. When excited by the green light photon, a defect center emits a red light photon. But, the direction that the red light photon may be emitted from the defect center is not necessarily the direction that the green light photon was received. Rather, the red light photon can be emitted in any direction. In some implementations, the sides of the magneto-optical defect center materials are angled and polished to reflect red light photons towards the photo sensor.

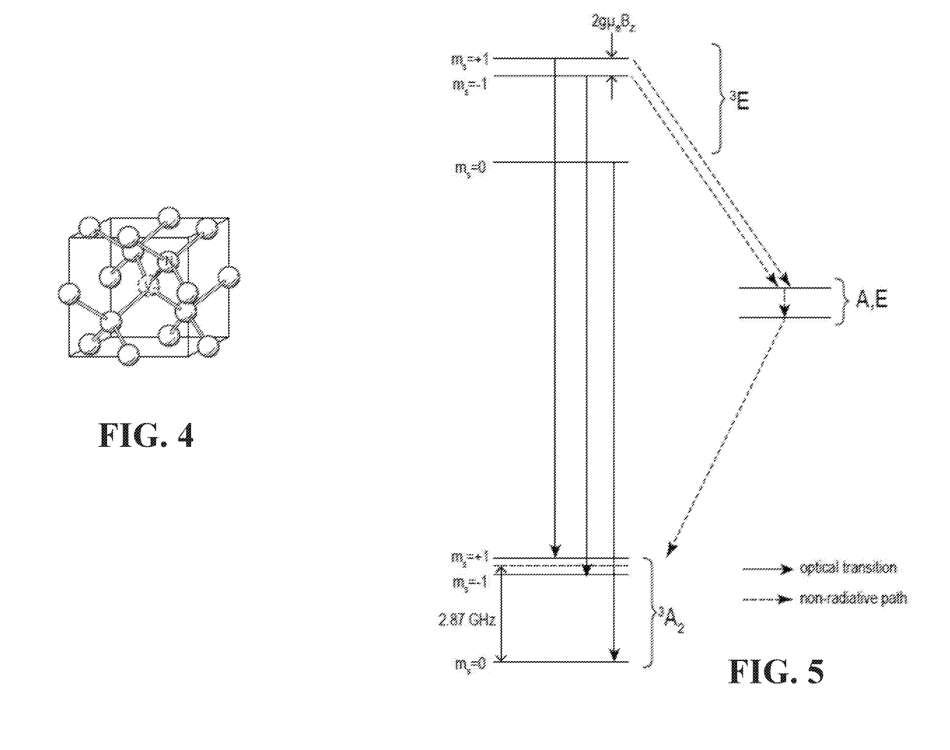

In some implementations, the magneto-optical defect center material may be a diamond where the NV center in the diamond comprises a substitutional nitrogen or boron atom in a lattice site adjacent a carbon vacancy as shown in FIG. 4. The NV center may have four orientations, each corresponding to a different crystallographic orientation of the diamond lattice.

The NV center may exist in a neutral charge state or a negative charge state. Conventionally, the neutral charge state uses the nomenclature NV₀, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which may be in the negatively charged state, also includes an extra electron.

The NV center has rotational symmetry, and as shown in FIG. 5, has a ground state, which may be a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level may be split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels ms=±1 by an amount 2 gμ_{B}B_{z}, where g is the g-factor, μ_{B} is the Bohr magneton, and B_{z} is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light may be emitted with a photon energy corresponding to the energy difference between the energy levels of the transitions.

There may be, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

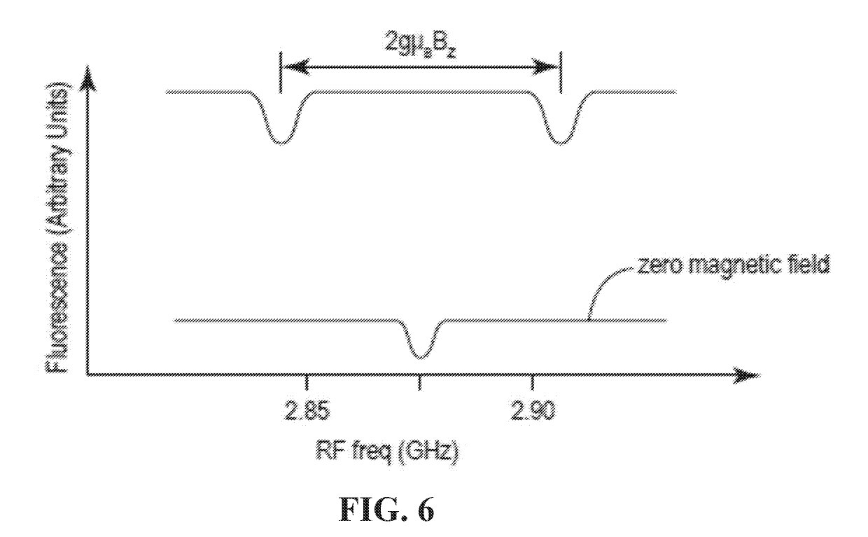

For continuous wave excitation, the optical excitation source 100 continuously pumps the defect centers, and the RF excitation source 330 sweeps across a frequency range that includes the zero splitting (when the mₛ=±1 spin states have the same energy) photon energy of 2.87 GHz. The fluorescence for an RF sweep corresponding to a magneto-optical defect center material 320 with defect centers aligned along a single direction is shown in FIG. 6 for different magnetic field components B_{z} along the deect center axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence, and spin echo pulse sequence. The excitation scheme utilized during the measurement collection process (i.e., the applied optical excitation and the applied RF excitation) may be any appropriate excitation scheme. For example, the excitation scheme may utilize continuous wave (CW) magnetometry, pulsed magnetometry, and variations on CW and pulsed magnetometry (e.g., pulsed RF excitation with CW optical excitation). In cases where Ramsey pulse RF sequences are used, pulse parameters 7C and T may be optimized using Rabi analysis and FID-Tau sweeps prior to the collection process, as described in, for example, U.S. patent application Ser. No. 15/003,590, which is incorporated by reference herein in its entirety.

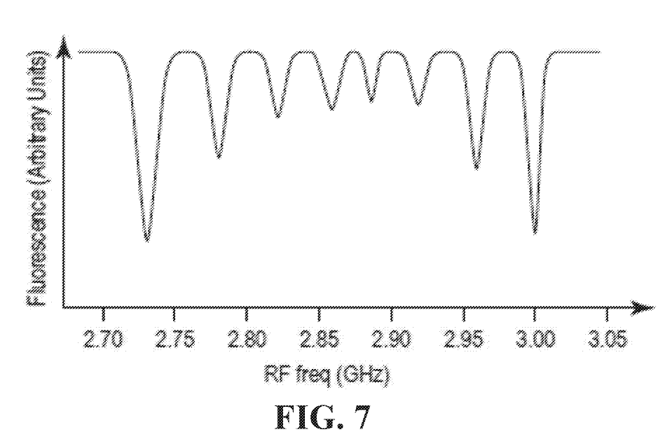

In general, the magneto-optical defect center material 320 has defect centers aligned along directions of four different orientation classes. FIG. 7 illustrates fluorescence as a function of RF frequency for the case where the magneto-optical defect center material 320 has defect centers aligned along directions of four different orientation classes. In this case, the component B_{z} along each of the different orientations may be determined. These results, along with the known orientation of crystallographic planes of a magneto-optical defect center material lattice, allow not only the magnitude of the external magnetic field to be determined, but also the direction of the magnetic field.

In general, the magnetic sensor system may employ a variety of different magneto-optical defect center material, with a variety of magneto-optical defect centers. Magneto-optical defect center materials include but are not be limited to diamonds, Silicon Carbide (SiC) and other materials with nitrogen, boron, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

The embodiments of the inventive concepts disclosed herein have been described in detail with particular reference to preferred embodiments thereof, but it will be understood by those skilled in the art that variations and modifications can be effected within the spirit and scope of the inventive concepts.

In an illustrative embodiment, any of the operations described herein can be implemented at least in part as computer-readable instructions stored on a computer-readable memory. Upon execution of the computer-readable instructions by a processor, the computer-readable instructions can cause a node to perform the operations.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. A system for magnetic detection, comprising:
a magneto-optical defect center material comprising a plurality of magneto-optical defect centers;
a radio frequency (RF) excitation source configured to provide RF excitation to the magneto-optical defect center material;
an optical detector configured to receive an optical signal emitted by the magneto-optical defect center material;
an optical light source; and
an optical waveguide assembly comprising an optical waveguide with a hollow core and at least one optical filter coating, wherein the optical waveguide assembly is configured to transmit light emitted from the magneto-optical defect center material to the optical detector through the at least one optical filter coating.

2. The system of claim 1, wherein the optical waveguide comprises a metallic light pipe comprising the hollow core, the metallic light pipe coated on the inner surface with silver.

3. The system of claim 1, wherein the optical filter coating transmits greater than about 99% of light with a wavelength of about 650 nm to about 850 nm.

4. The system of claim 1, wherein the optical filter coating transmits less than 0.1% of light with a wavelength of less than about 600 nm.

5. The system of claim 1, wherein the optical filter coating transmits greater than about 99% of light with a wavelength of about 650 nm to about 850 nm, and transmits less than 0.1% of light with a wavelength of less than about 600 nm.

6. The system of claim 1, wherein the optical filter coating is disposed on an end surface of the optical waveguide adjacent the optical detector.

7. The system of claim 1, wherein a first optical filter coating is disposed on an end surface of the optical waveguide adjacent the optical detector, and a second optical filter coating is disposed on an end surface of the optical waveguide adjacent the magneto-optical defect center material.

8. The system of claim 2, wherein the light pipe has an aperture with a size that is smaller than a size of the optical detector.

9. The system of claim 2, wherein the light pipe has an aperture with a size greater than a size of a surface of the magneto-optical defect center material adjacent to the light pipe.

10. The system of claim 2, wherein the light pipe has an aperture with a size that is smaller than a size of the optical detector and greater than a size of a surface of the magneto-optical defect center material adjacent the light pipe.

11. The system of claim 2, wherein the optical waveguide assembly further comprises an optical coupling material disposed between the light pipe and the magneto-optical defect center material, and the optical coupling material is configured to optically couple the light pipe to the magneto-optical defect center material.

12. The system of claim 2, wherein the optical waveguide assembly further comprises an optical coupling material disposed between the light pipe and the optical detector, and the optical coupling material is configured to optically couple the light pipe to the optical detector.

13. The system of claim 2, wherein an end surface of the light pipe adjacent to the magneto-optical defect center material extends in a plane parallel to a surface of the magneto-optical defect center material adjacent to the light pipe.

14. The system of claim 1, further comprising a second optical waveguide assembly and a second optical detector, wherein the optical waveguide assembly is configured to transmit light emitted from the magneto-optical defect center material to the optical detector.

15. A method for magnetic detection using a magneto-optical defect center material comprising a plurality of magneto-optical defect centers, the method comprising:
providing radio frequency (RF) excitation to the magneto-optical defect center material by an RF excitation source;
transmitting light emitted from the magneto-optical defect center material to an optical detector using a waveguide assembly comprising an optical waveguide with a hollow core and through at least one optical filter coating; and
receiving an optical signal comprising the light emitted by the magneto-optical defect center material by the optical detector.

16. The method of claim 15, wherein the optical waveguide comprises a light pipe with an inner surface coating of silver.

17. The method of claim 15, wherein the optical filter coating transmits greater than about 99% of light with a wavelength of about 650 nm to about 850 nm.

18. The method of claim 15, wherein the optical filter coating transmits less than 0.1% of light with a wavelength of less than about 600 nm.

19. The method of claim 15, wherein the optical filter coating transmits greater than about 99% of light with a wavelength of about 650 nm to about 850 nm, and transmits less than 0.1% of light with a wavelength of less than about 600 nm.

20. A system for magnetic detection, comprising:
a magneto-optical defect center material comprising a plurality of magneto-optical defect centers;
a means for providing RF excitation to the magneto-optical defect center material;
a means for receiving an optical signal emitted by the magneto-optical defect center material by an optical detector;
an optical light source; and
a means for transmitting light emitted from the magneto-optical defect center material to the optical detector using an optical waveguide with a hollow core and at least one optical filter coating.

21. A magneto-optical defect center magnetometer comprising:
a magneto-optical defect center material comprising a plurality of magneto-optical defect centers;
a lens assembly with a red filter configured to direct light from the magneto-optical defect center material; and
a light pipe configured to operably connect to the lens assembly to transmit red light.

22. The magneto-optical defect center magnetometer of claim 21, further comprising an optical light source configured to direct light at the magneto-optical defect center material.

23. The magneto-optical defect center magnetometer of claim 22, further comprising a laser position adjustment flexure rib array configured to adjust a position of the optical light source, wherein the optical light source is a laser diode.

24. The magneto-optical defect center magnetometer of claim 23, further comprising a laser angle adjustment flexure rib configured to adjust an angle of the optical light source.

25. The magneto-optical defect center magnetometer of claim 21, further comprising an optical excitation focusing lens cell and a photo diode, wherein the optical excitation focusing lens cell is configured to focus light coming from an exit of the light pipe on to the photo diode.

26. The magneto-optical defect center magnetometer of claim 21, wherein the light pipe comprises a metallic light pipe comprising a hollow core, coated on the inner surface with silver.
